(19) United States
(12) Patent Application Publication
(10) Pub. No.: US 2010/0002381 A1
(43) Pub. Date: Jan. 7, 2010

(54) HEAT DISSIPATION DEVICE AND METHOD FOR MOUNTING THE SAME

(75) Inventors: XU-XIN MIN, Shenzhen City (CN); MENG FU, Shenzhen City (CN); CHUN-CHI CHEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/238,439

(22) Filed: Sep. 26, 2008

(30) Foreign Application Priority Data
Jul. 4, 2008 (CN) 200810068322.4

(51) Int. Cl. H05K 7/20; H05K 13/04

(52) U.S. Cl. 361/694; 29/729

(57) ABSTRACT

A heat dissipation device used for dissipating heat generated by an electronic device comprises a base defining two cutouts recessed from two opposite sides thereof, two fasteners mounted in through holes of the base via the two cutouts and two elastic members coiled around the two fasteners. Each of the two fasteners comprises a shaft, a head and a threaded pole located at two ends of the shaft, a latching portion interconnecting the shaft and the threaded pole and a mounting portion which is formed on the shaft and located a distance above the latching portion. The mounting portion extends through the cutout and makes the elastic member be sandwiched elastically between the head and a top face of the base. The latching portion abuts against a bottom face of the base, thereby the two fasteners being mounted on the base.

### BACKGROUND

1. Field of the Invention

The present invention relates to a heat dissipation device and a method for mounting the heat dissipation device, more particularly to a heat dissipation device used for dissipating heat generated by an electronic device and a method for mounting the heat dissipation device to the electronic device.

2. Description of Related Art

It is well known that, during operation of a computer, electronic devices such as central processing units (CPUs) frequently generate large amounts of heat. The heat must be quickly removed from the electronic device to prevent it from becoming unstable or being damaged. Typically, a heat dissipation device is attached to an outer surface of the electronic device to absorb heat generated by the electronic device. A fastener is needed to keep the heat dissipation device in tight contact with the electronic device.

Referring to FIG. 5, a conventional heat dissipation device includes a heat sink 10 and a fastener 20 for keeping the heat sink 10 in contact with an electronic device 60 mounted on a printed circuit board 50. The heat sink 10 comprises a base 12 and a fin unit 14 mounted on the base 12. Two through holes 16 are defined close to centers of two opposite sides of the base 12 respectively. The fin unit 14 defines two cutouts 142 corresponding to the through holes 16. The fastener 20 comprises a head 22, a shaft 24 extending downwardly from the head 22 and a threaded pole 26 extending downwardly from the shaft 24 continuously. An annular groove 28 is defined in a bottom end of the shaft 24 and closes to the threaded pole 26. Referring to FIG. 6 also, in a process of mounting the fastener 20 on the heat sink 10, firstly, a spring 30 circles around the shaft 24 of the fastener 20, and then the fastener 20 with the spring 30 extends through the through hole 16 from a top to a bottom of the base 12, at the same time, a pressure is exerted on the fastener 20 downwardly and makes the groove 28 extend beyond a bottom face of the base 12. Finally, a retaining collar 40 is received in the groove 28 to clasp the shaft 24 and abuts against the bottom face of the base 12. In use of the heat dissipation device, the fastener 20 is in alignment with a through hole 52 of the printed circuit board 50 and extends through the through hole 52, and then engages threadedly with a back plate 70 located under the printed circuit board 50. By doing this, the heat dissipation device is secured on the printed circuit board 50 and is in contact with the electronic device 60 to dissipate heat generated by the electronic device 60.

However, the clasping of the retaining collar 40 on the shaft 24 of the fastener 20 in the groove 28 is not always reliable since resilient fingers (not labeled) of the retaining collar 40 which are elastically deformed during the assembly may be broken from the retaining collar 40. Furthermore, it needs to press the fastener 200 with a large force to overcome the elastic force of the spring 30 to push the groove 28 of the shaft 24 downwardly beyond the bottom face of the base 12, whereby retaining collar 40 can be mounted to the shaft 24. This makes it difficult to assemble the fastener 20 and the heat sink 10 together.

what is needed, therefore, is a heat dissipation device provided with a fastener which can be conveniently assembled with the heat sink.

### SUMMARY

A heat dissipation device used for dissipating heat generated by an electronic device comprises a base defining two cutouts, two fasteners mounted on the base via the two cutouts and two elastic members coiled around the two fasteners. Each of the two fasteners comprises a shaft, a head and a threaded pole located at two ends of the shaft, a latching portion connecting the shaft and the threaded pole and a mounting portion which is formed on the shaft and has a certain distance with the latching portion. The mounting portion extends through the cutout and makes the elastic member be sandwiched elastically between the head and a top face of the base. The latching portion abuts against a bottom face of the base, thereby the two fasteners being mounted on the base.

Other advantages and novel features of the present invention will become more apparent from the following detailed description of an embodiment/embodiments when taken in conjunction with the accompanying drawings.

### BRIEF DESCRIPTION OF THE DRAWINGS

Many aspects of the present invention can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is an exploded, isometric view of a heat dissipation device and interrelated components in accordance with a preferred embodiment of the present invention.

FIG. 2 is a front elevational view of a fastener and a spring of the heat dissipation device of FIG. 1.

FIG. 3 is a side, assembled view of the heat dissipation device of FIG. 1 with the fastener in an unlocked state.

FIG. 4 is a side, assembled view of the heat dissipation device of FIG. 1 with the fastener in a locked state.

FIG. 5 is a partial, assembled view of a heat dissipation device and interrelated components in accordance with related art.

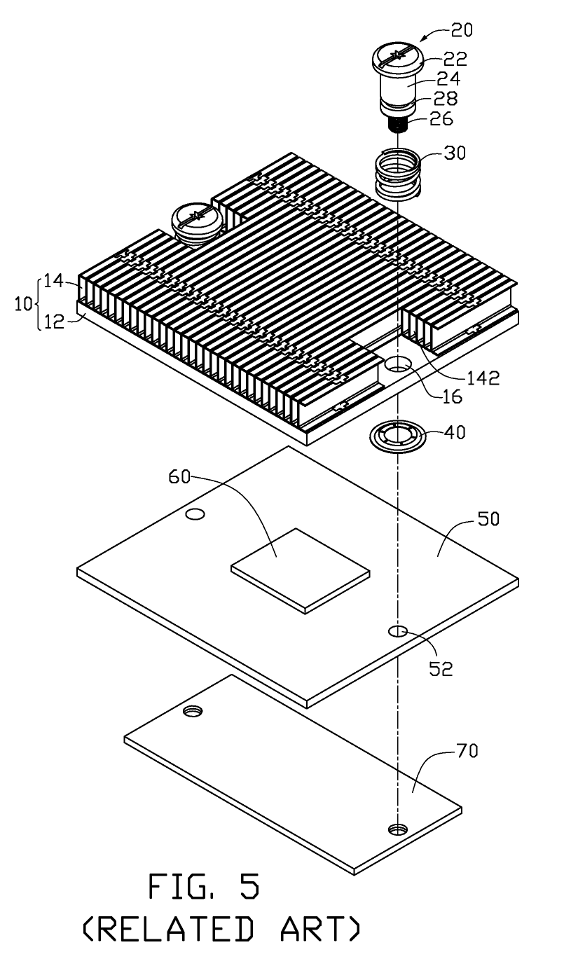

FIG. 6 is a side, assembled view of the heat dissipation device of FIG. 5.

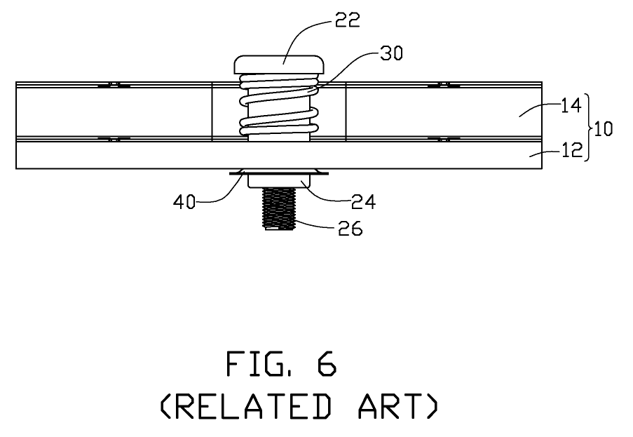

### DETAILED DESCRIPTION

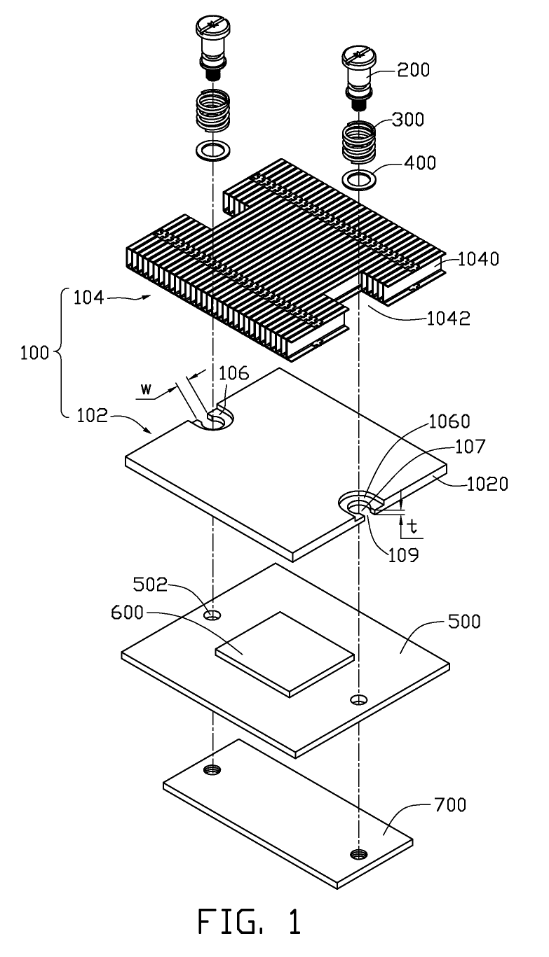

Referring to FIG. 1, a heat dissipation device in accordance with a preferred embodiment of the present invention comprises a heat sink 100 and a fastener 200 fastening the heat sink 100 on a printed circuit board 500 by assistant of a back plate 700 to dissipate heat generated by an electronic device 600 mounted on the printed circuit board 500.

The heat sink 100 comprises a plate-shaped base 102 and a fin unit 104 attached on a top face of the base 102. Two steps 106 each of which has a substantially U-shaped configuration are defined close to centers of two opposite sides of the base 102 respectively. The step 106 has a top surface 1060 lower than the top face of the base 102, and the step 106 is communicated with a side face 1020 of the base 102 and has an exit at the side face 1020. A through hole 107 is defined in a center of the step 106. A cutout 109 is defined in the step 16 and extends through the side face 1020 of the base 102 to be in communication with an environment and the through hole 107. The cutout 109 is located between the environment and the through hole 107. The fin unit 104 is composed of a plurality of fins 1040. These fins 1040 are connected together via a locking structure. Some of the plurality of fins 1040 corresponding to the step 106 cooperatively define a gap 1042 in order to facilitate the fastener 200 extending through the through hole 107 defined in the step 106.

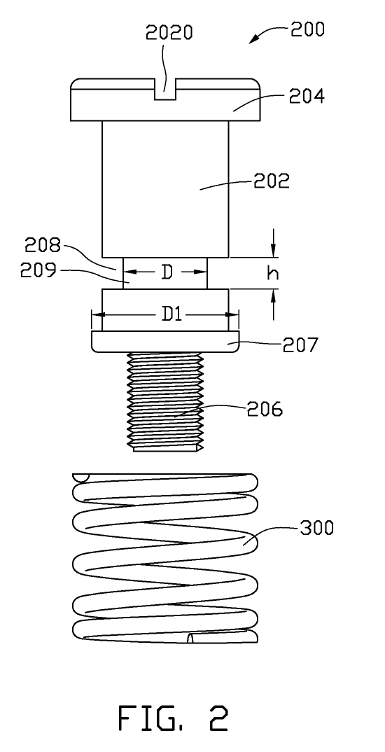

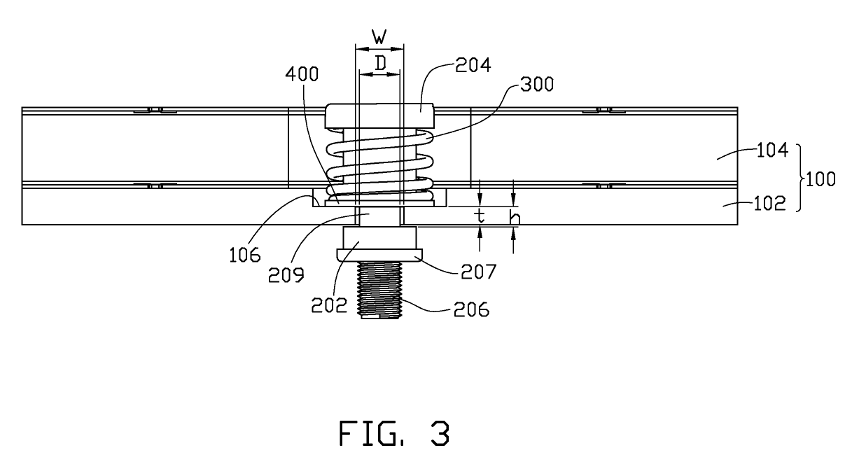

Referring to FIG. 2 also, the fastener 200 comprises a shaft 202, a disc-shaped head 204 and a threaded pole 206 located at two ends of the shaft 202 respectively. The threaded pole 206 is machined with threads onto an exterior thereof. A latching portion 207 connects the shaft 202 and the threaded pole 206 and circumferentially protrudes from and beyond the exterior of the shaft 202. The head 204 defines a cross-shaped groove 2020 in a top thereof for facilitating operation of a tool such as a screwdriver thereon. An annular slot 208 is defined in the shaft 202 and adjacent to the latching portion 207, and a mounting portion 209 is formed corresponding to the slot 208. There is a certain distance between the mounting portion 209 and the latching portion 207. A cross-section of the mounting portion 209 in the preferred embodiment is round. It is understood that the mounting portion 209 can be designed to have other configurations in different embodiments. Referring to FIG. 3 also, a spring 300 and a washer 400 extend sequentially through the threaded pole 206 and then surround the shaft 202. A diameter D of the mounting portion 209 is less than a width W of the cutout 109 of the base 102. A vertical height h of the mounting portion 209 is larger than a distance t between the top surface 1060 of the step 106 and a bottom face of the base 102. By such design, the mounting portion 209 can extend through the cutout 109 from the side face 1020 of the base 102 and further extend into the through hole 107. A diameter of the shaft 202 is slightly less than that of the through hole 107 defined in the base 102 to make sure that the shaft 202 can extend through the through hole 107. A diameter D1 of the latching portion 207 is larger than that of the through hole 107 of the base 102 to make sure that the latching portion 207 can abut against the bottom face of the base 102 and prevent the fastener 200 from detaching from the through hole 107 in use. The diameter of the shaft 202 is larger than the width w of the cutout 109 to prevent the shaft 202 from leaving the base 102 from the cutout 109.

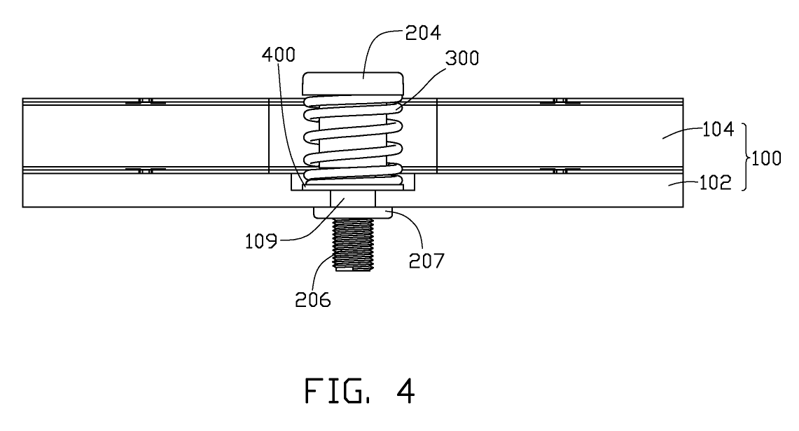

Referring to FIGS. 3-4 also, in a process of assembling the heat dissipation device of the present invention, firstly, the spring 300 and the washer 400 are sequentially mounted around the shaft 202 of the fastener 200. Secondly, a pressure is upwardly exerted on the spring 300 via the washer 400 to compress the spring 300 upwards to such an extent that the mounting portion 209 extends downwardly beyond the washer 400. At the same time, the mounting portion 209 is moved to extend into the cutout 109 from the side face 1020 of the base 102 and further extend into the through hole 107 as viewed in FIG. 3. Finally, the pressure exerted on the spring 300 is released, and the spring 300 is still in an elastically deformed state, compressed between the head 204 and the washer 400 which is now sitting on the step 106. The shaft 202 located between the mounting portion 209 and the latching portion 207 extends in the through hole 107 of the base 102, the latching portion 207 abuts against the bottom face of the base 102 and the washer 400 presses on the surface 1060 of the step 106 as a results of an elastic force provided by the spring 300. The spring 300 is kept in an elastically deformed state as viewed in FIG. 4. The assembly of the heat dissipation device in accordance with present invention is completed thereby.

Referring to FIG. 1 also, In use of the heat dissipation device of the present invention, the fastener 200 is in alignment with a through hole 502 of the printed circuit board 500 and extends through the through hole 502 and then engages threadedly with the back plate 700 located under the printed circuit board 500. By doing this, the heat dissipation device is fastened on the printed circuit board 500 and is in tight contact with the electronic device 600 to dissipate heat generated by the electronic device 600.

According to the preferred embodiment of the present invention, the heat dissipation device is assembled by simply pressing the spring 300 and the washer 400 mounted around the shaft 202 of the fastener 200 to make the mounting portion 209 be located below the washer 400 and further extending the mounting portion 209 into the through hole 107 defined in the base 102 via the cutout 109 along a side direction. In a disassembly of the heat dissipation device, it only needs to press the head 204 of the fastener 200 downwardly to make the mounting portion 209 extend into the through hole 107 and further move the mounting portion 209 sideward from the base 102 through the cutout 109 without using any tools.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation device used for dissipating heat generated by an electronic device comprising:
a base defining two cutouts recessed from two opposite sides thereof and two through holes in communication with the cutouts, respectively, a diameter of the each of the through holes being larger than a width of a corresponding cutout;
a fin unit on a top face of the base;
two fasteners mounted in the through holes of the base via the two cutouts, wherein each of the two fasteners comprises a shaft;
a latching portion formed at an end of the shaft and abutting against a bottom face of the base; and
an elastic member coiled around the shaft and elastically abutting against the top face of the base.

2. The heat dissipation device as claimed in claim 1, wherein the shaft defines a slot close to the latching portion, the shaft corresponding to the slot forms a mounting portion of which a diameter is less than that of the shaft.

3. The heat dissipation device as claimed in claim 2, wherein there is a distance between the mounting portion and the latching portion.

4. The heat dissipation device as claimed in claim 2, wherein the diameter of the mounting portion is less than a width of each of the two cutouts, and a height of the mounting portion is larger than a depth of each of the two through holes.

5. The heat dissipation device as claimed in claim 4, wherein the diameter of the shaft is larger than the width of each of the two cutouts.

6. The heat dissipation device as claimed in claim 1, wherein each of the two fasteners further comprises a head and a threaded pole located two ends of the shaft, and a washer is placed to the shaft and is sandwiched between the elastic member and the top face of the base.

7. The heat dissipation device as claimed in claim 1, wherein the fin unit defines two gaps corresponding to the two through holes of the base.

8. The heat dissipation device as claimed in claim 1, wherein the base defines two steps, and each of the two through holes is defined in a center of each of the two steps.

9. The heat dissipation device as claimed in claim 8, wherein each of the two steps has a U-shaped configuration.

10. The heat dissipation device as claimed in claim 8, wherein a top face of each of the two steps is lower than the top face of the base except for the two steps.

11. The heat dissipation device as claimed in claim 1, wherein the two cutouts are defined close to centers of the two opposite sides of the base respectively.

12. A method of mounting a heat dissipation device with a fastener, the heat dissipation device having a base, the method comprising steps:
providing the base with a through hole and a cutout communicated with the through hole and recessed from a side of the base, the through hole having a diameter larger than a width of the cutout;
offering the fastener, wherein the fastener comprises a shaft, a head and a threaded pole located at two ends of the shaft, a latching portion interconnecting the shaft and the threaded pole and a mounting portion which is formed on the shaft and is spaced a distance from the latching portion, the mounting portion being located above the latching portion and having a diameter less than that of the shaft which is less than that of the latching portion;
offering an elastic member;
coiling the elastic member around the shaft;
pressing the elastic member upwardly to make the mounting portion located below and out of the elastic member;
extending the mounting portion sideward through the cutout into the through hole; and
releasing the elastic member to make the latching portion abut against a bottom face of the base, whereby the fastener is attached to the base.
